(19) United States
(12) Patent Application Publication
(10) Pub. No.: US 2026/0279422 A1
(43) Pub. Date: Sep. 17, 2026

(54) MAGNETIC ARRAY, METHODS OF CONTROLLING MAGNETIC ARRAY, AND RECORDING MEDIA

(71) Applicant: TDK Corporation, Tokyo (JP)

(72) Inventor: Shogo YAMADA, Tokyo (JP)

(73) Assignee: TDK Corporation, Tokyo (JP)

(21) Appl. No.: 19/548,079

(22) Filed: Feb. 24, 2026

Related U.S. Application Data
(60) Provisional application No. 63/766,601, filed on Mar. 4, 2025.

(51) Int. Cl. G11C 11/16; H01F 7/06; H10B 61/00; H10N 50/10; H10N 50/20; H10N 50/80

(52) U.S. Cl. CPC G11C 11/161; G11C 11/1675; G11C 11/1693; H01F 7/064; H10B 61/22; H10N 50/10; H10N 50/20; H10N 50/80

(57) ABSTRACT

This magnetic array includes a plurality of memristors and a pulse application device. The pulse application device is configured to be capable of applying, as write pulses, a magnetic domain wall driving pulse and a mode change pulse to at least one of the plurality of memristors. In a process of updating a conductance, the pulse application device is configured to be capable of determining whether or not application of the mode change pulse is necessary based on the conductance of a laminate before updating and the conductance of the laminate after updating. The mode change pulse has a longer pulse length than the magnetic domain wall driving pulse. In one process of updating the conductance, the number of times of application of the mode change pulse is equal to or smaller than the number of times of application of the magnetic domain wall driving pulse.

### TECHNICAL FIELD

The present disclosure relates to a magnetic array, methods of controlling a magnetic array, and recording media.

### BACKGROUND ART

Memristors are passive elements which store electric charge that has passed therethrough, whereby their conductance or resistance varies accordingly. Memristors are a new class of passive elements following resistors, capacitors, and inductors. Memristors output a current corresponding to the product of an input voltage and their conductance value. For example, as described in Non-Patent Document 1, memristors can be utilized in neuromorphic devices that mimic brain functions.

In addition, Non-Patent Document 2 also discloses a spin memristor in which a conductance in a lamination direction varies depending on the position of a magnetic domain wall, enabling multi-value data storage. Spin memristors exhibit excellent linearity and symmetry in operation and are readily applicable to neuromorphic devices.

### CITATION LIST

### Non-Patent Documents

Non-Patent Document 1: Geoffrey W. Burr et al., Advances in Physics. X 2, 2017 Vol. 2, No. 1, 89-124
Non-Patent Document 2: T. Shibata et al., Appl. Phys. Express 13, 043004 (2020)

### SUMMARY OF INVENTION

### Technical Problem

In order to handle a large amount of information with a single element, it is preferable for a memristor to have a large number of conductance levels. Methods of increasing the number of conductance levels of a memristor include increasing the element length, changing the material constituting a magnetic domain wall motion layer where a magnetic domain wall moves, shortening the write pulse applied to the memristor, and the like. However, increasing the element length may cause deterioration in integration of the memristor, changing the material of a magnetic domain wall motion layer may not be easy due to various limitations, and shortening the write pulse may reduce the probability of desired conductance change.

The present disclosure been made in consideration of the foregoing problems, and an object thereof is to provide a magnetic array, methods of controlling a magnetic array, and recording media capable of increasing the number of conductance levels using a new technique.

### Solution to Problem

A magnetic array according to a first aspect includes a plurality of memristors and a pulse application device. The pulse application device is configured to be capable of applying, as write pulses, a magnetic domain wall driving pulse and a mode change pulse to at least one of the plurality of memristors. Each of the plurality of memristors includes a magnetic domain wall motion layer, a ferromagnetic layer, and a nonmagnetic layer. The nonmagnetic layer is sandwiched between the magnetic domain wall motion layer and the ferromagnetic layer. A conductance of a laminate including the magnetic domain wall motion layer, the ferromagnetic layer, and the nonmagnetic layer varies depending on a change in position of a magnetic domain wall in the magnetic domain wall motion layer. In a process of updating the conductance, the pulse application device is configured to be capable of determining whether or not application of the mode change pulse is necessary based on the conductance of the laminate before updating and the conductance of the laminate after updating. The mode change pulse has a longer pulse length than the magnetic domain wall driving pulse. In one process of updating the conductance, the number of times of application of the mode change pulse is equal to or smaller than the number of times of application of the magnetic domain wall driving pulse.

### Advantageous Effects of Invention

The magnetic array, the methods of controlling a magnetic array, and the recording media according to the foregoing aspect are capable of increasing the number of conductance levels of an element using a new technique.

### BRIEF DESCRIPTION OF DRAWINGS

FIG. 1 A block diagram of a magnetic array according to a first embodiment.

FIG. 2 A circuit diagram of an integrated area of the magnetic array according to the first embodiment.

FIG. 3 A cross-sectional view of a part in the vicinity of a magnetic domain wall motion element of the magnetic array according to the first embodiment.

FIG. 4 A cross-sectional view of the magnetic domain wall motion element according to the first embodiment.

FIG. 5 A plan view of the magnetic domain wall motion element according to the first embodiment.

FIG. 6 A schematic diagram showing relationships between positions of a magnetic domain wall, a movement amount of the magnetic domain wall, and a conductance change amount when the magnetic domain wall is moved using only a magnetic domain wall motion pulse in the magnetic domain wall motion element according to the first embodiment.

FIG. 7 A schematic diagram showing relationships between the positions of the magnetic domain wall, the movement amounts of a magnetic domain wall DW, and the conductance change amounts when the magnetic domain wall is moved using a magnetic domain wall motion pulse and a mode change pulse in the magnetic domain wall motion element according to the first embodiment.

FIG. 8 A schematic diagram showing relationships between the positions of the magnetic domain wall, the movement amounts of the magnetic domain wall DW, and the conductance change amounts when the magnetic domain wall is moved using a magnetic domain wall motion pulse and a plurality of mode change pulses in the magnetic domain wall motion element according to the first embodiment.

FIG. 9 A cross-sectional view of a modification example of the magnetic domain wall motion element according to the first embodiment.

FIG. 10 A flowchart of a write operation of the magnetic array according to the first embodiment.

FIG. 11 A schematic diagram of a neural network.

### DESCRIPTION OF EMBODIMENT

Hereinafter, the present embodiment will be described in detail suitably with reference to the drawings. In the drawings used in the following description, in order to make characteristics of the present disclosure easy to understand, characteristic parts may be shown in an enlarged manner for the sake of convenience, and dimensional ratios or the like of each constituent element may differ from actual values thereof. Materials, dimensions, and the like shown in the following description are merely exemplary examples. The present disclosure is not limited thereto and can be suitably changed and performed within a range in which the effects of the present disclosure are exhibited.

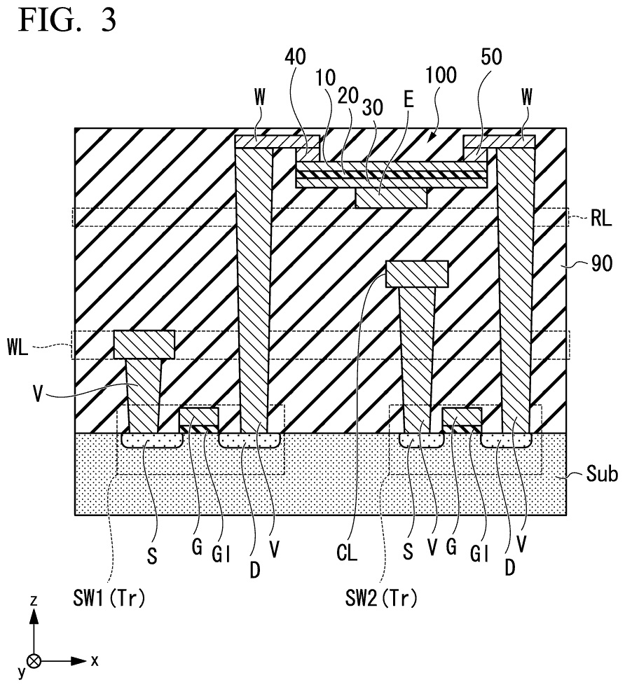

First, directions will be defined. An x direction and a y direction are directions substantially parallel to a surface of a substrate Sub (refer to FIG. 3), which will be described below. The x direction is a direction in which a magnetic domain wall motion layer 10 (which will be described below) extends. The y direction is a direction orthogonal to the x direction within an xy plane. A z direction is a direction toward a magnetic domain wall motion element 100 from the substrate Sub, which will be described below. In this specification, the positive z direction may be expressed as “upward”, and the negative z direction may be expressed as “downward”, but these expressions are used for the sake of convenience and do not define the direction of gravity. In addition, in this specification, for example, the expression “extending in the x direction” means that the dimension in the x direction is larger than the smallest dimension among respective dimensions in the x direction, the y direction, and the z direction. The same applies to the cases of extending in other directions. In addition, in this specification, the term “connect” is not limited to the case of being directly connected and also includes a case of being connected with another object therebetween.

### First Embodiment

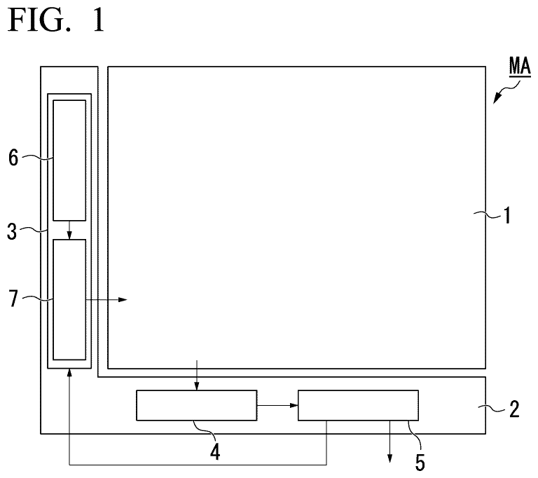

FIG. 1 is a block diagram of a magnetic array MA according to a first embodiment. The magnetic array MA has an integrated area 1 and a peripheral area 2. For example, the magnetic array MA can be utilized in magnetic memories, product-sum operation units, neuromorphic devices, spin memristors, and magneto-optic elements.

The integrated area 1 is an area in which a plurality of magnetic domain wall motion elements are integrated. The magnetic domain wall motion element is an example of a memristor.

When the magnetic array MA is used as a memory, data is accumulated in the integrated area 1. When the magnetic array MA is used as a neuromorphic device, learning and inference are performed in the integrated area 1.

The peripheral area 2 is an area in which a control element for controlling operation of the magnetic domain wall motion elements within the integrated area 1 is mounted. For example, the peripheral area 2 has a pulse application device 3, a resistance detection device 4, and an output unit 5.

The pulse application device 3 is configured to be capable of applying a pulse to at least one of the plurality of magnetic domain wall motion elements within the integrated area 1. For example, the pulse application device 3 has a control unit 6 and a power source 7.

For example, the control unit 6 has a processor and a memory. For example, the processor is a central processing unit (CPU) or the like. The processor executes a control program stored in the memory. The control program includes a write program, which will be described below. All or a part of functions of the processor may be realized using hardware such as an application specific integrated circuit (ASIC), a programmable logic device (PLD), or a field programmable gate array (FPGA).

The memory is a recording medium capable of storing the control program. Details of the control program stored in the memory will be described below. The recording medium may be a magnetic hard disk device, a semiconductor storage device, or the like, and is a computer-readable recording medium. For example, a computer-readable recording medium refers to a portable medium such as a flexible disk, a magneto-optical disk, a ROM, a CD-ROM, or a semiconductor storage device (for example, SSD: a solid state drive), as well as a storage device such as a hard disk or a semiconductor storage device built into a computer system.

For example, the control unit 6 controls an address of a magnetic domain wall motion element to which a pulse is to be applied, a write pulse (voltage, pulse length) applied to a predetermined magnetic domain wall motion element, and the like. Furthermore, the control unit 6 may have a clock, a counter, a random number generator, and the like. The clock serves as an indicator for a timing of application of a pulse, and the counter counts the number of times a pulse has been applied, or the like. The power source 7 applies a pulse toward the magnetic domain wall motion elements in response to an instruction from the control unit 6.

The resistance detection device 4 is configured to be capable of detecting resistance values of the magnetic domain wall motion elements within the integrated area 1. The resistance detection device 4 may detect resistances of the respective magnetic domain wall motion elements within the integrated area 1. For example, it may detect the total resistance of the magnetic domain wall motion elements which belong to the same column. For example, the resistance detection device 4 may have a comparator which compares magnitudes of detected resistance values. For example, the comparator may compare detected resistance values with each other or may compare a reference resistance value set in advance with detected resistance values.

The output unit 5 is connected to the resistance detection device 4. For example, the output unit 5 has a processor, an output capacitor, an amplifier, a converter, and the like. When the magnetic array MA is used as a neuromorphic device, the output unit 5 may perform arithmetic operation of substituting detection results of the resistance detection device 4 into an activation function. For example, the arithmetic operation is performed by the processor. The output unit 5 outputs the arithmetic operation results to the outside. When the magnetic array MA is used as a neuromorphic device, for example, an operation, such as outputting arithmetic operation results as an input signal of another magnetic array, may be performed, or an operation, such as outputting it to the outside as an identification rate, may be performed. In addition, the output unit 5 may also feed back the arithmetic operation results to the pulse application device 3.

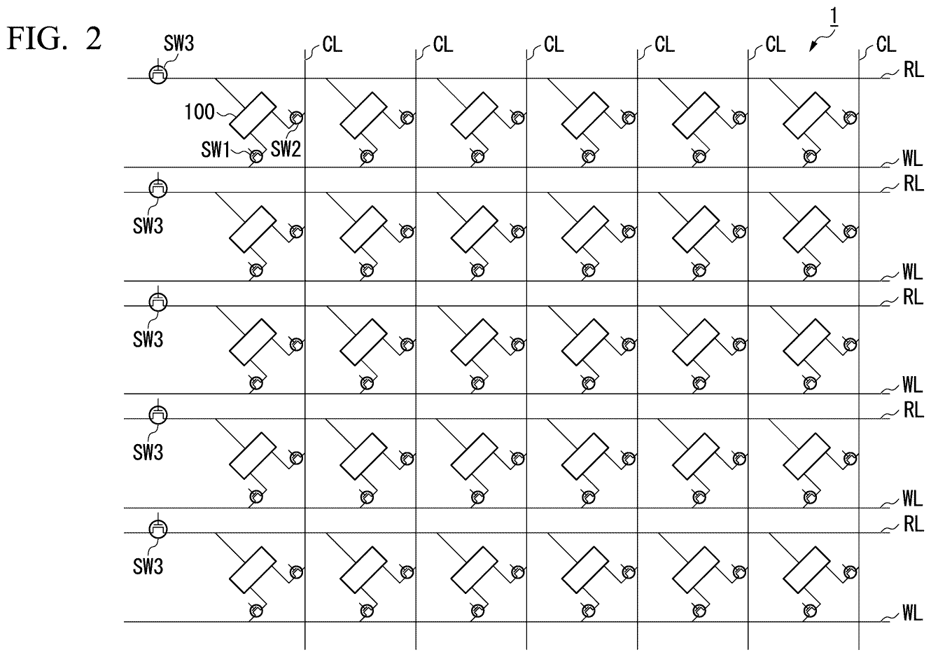

FIG. 2 is a circuit diagram of the integrated area 1 according to the first embodiment. The integrated area 1 includes a plurality of magnetic domain wall motion elements 100, a plurality of first wirings WL, a plurality of second wirings CL, a plurality of third wirings RL, a plurality of first switching elements SW1, and a plurality of second switching elements SW2. For example, third switching elements SW3 may belong to the pulse application device 3 of the peripheral area 2.

For example, the plurality of magnetic domain wall motion elements 100 are arrayed in a matrix shape. The plurality of magnetic domain wall motion elements 100 are not limited to those in which real elements are arrayed in a matrix shape and may be arrayed in a matrix in a circuit diagram.

Each of the first wirings WL is a write wiring. Each of the first wirings WL electrically connects the pulse application device 3 and one or more magnetic domain wall motion elements 100 to each other. Each of the second wirings CL is a common wiring which can be used both when writing and reading data. For example, each of the second wirings CL is connected to the resistance detection device 4. The second wiring CL may be provided in each of the plurality of magnetic domain wall motion elements 100 or may be provided across the plurality of magnetic domain wall motion elements 100. Each of the third wirings RL is a read wiring. Each of the third wirings RL electrically connects the pulse application device 3 and one or more magnetic domain wall motion elements 100 to each other.

The first switching elements SW1, the second switching elements SW2, and the third switching elements SW3 are elements for controlling a flow of a current. For example, the first switching elements SW1, the second switching elements SW2, and the third switching elements SW3 are transistors. For example, the first switching elements SW1, the second switching elements SW2, and the third switching elements SW3 may be elements such as ovonic threshold switches (OTS) utilizing phase change in a crystal layer, elements such as metal insulator transfer (MIT) switches utilizing variation in a band structure, elements such as Zener diodes and avalanche diodes utilizing a breakdown voltage, or elements whose conductivity varies in accordance with variation in atom positions.

For example, the first switching elements SW1 and the second switching elements SW2 are each connected to one magnetic domain wall motion element 100. For example, the first switching element SW1 is connected between the magnetic domain wall motion element 100 and the first wirings WL. For example, the second switching element SW2 is connected between the magnetic domain wall motion element 100 and the second wirings CL. For example, the third switching element SW3 is connected across the plurality of magnetic domain wall motion elements 100. For example, the third switching element SW3 is connected to the third wirings RL.

The positional relationships between the first switching elements SW1, the second switching elements SW2, and the third switching elements SW3 are not limited to the case shown in FIG. 2. For example, the first switching element SW1 may be connected across the plurality of magnetic domain wall motion elements 100 and positioned upstream of the first wirings WL. In addition, for example, the second switching element SW2 may be connected across the plurality of magnetic domain wall motion elements 100 and positioned upstream of the second wirings CL. In addition, for example, each of the third switching elements SW3 may be connected to one magnetic domain wall motion element 100.

FIG. 3 is a cross-sectional view of a part in the vicinity of the magnetic domain wall motion element 100 of the magnetic array MA according to the first embodiment. FIG. 3 is a cross section of the one magnetic domain wall motion element 100 in FIG. 2 cut along an xz plane passing through the center of the width of the magnetic domain wall motion layer 10 in the y direction.

The first switching element SW1 and the second switching element SW2 shown in FIG. 3 are transistors Tr. The transistor Tr has a gate electrode G, a gate insulation film GI, and a source S and a drain D formed on the substrate Sub. The source S and the drain D are prearranged depending on a flowing direction of a current, and these are the same areas. FIG. 3 merely shows an example, and the positional relationship between the source S and the drain D may be reversed. For example, the substrate Sub is a semiconductor substrate. The third switching element SW3 is electrically connected to the third wirings RL and is located at a position shifted in the x direction in FIG. 3, for example.

The transistors Tr, the first wirings WL, the second wirings CL, the third wirings RL, and the magnetic domain wall motion elements 100 are connected to each other by a via wiring V extending in the z direction or a wiring W extending in any direction within an xy plane. The via wiring V and the wiring W contain a conductive material. An insulation layer 90 is formed between different levels in the z direction except for the via wiring V.

The insulation layer 90 is an insulation layer providing insulation between wirings of a multilayer wiring or between elements. The magnetic domain wall motion element 100 and the transistor Tr are electrically separated by the insulation layer 90 except for the via wiring V. For example, the insulation layer 90 is made of silicon oxide (SiOₓ), silicon nitride (SiNₓ), silicon carbide (SiC), chromium nitride (CrN), silicon carbonitride (SiCN), silicon oxynitride (SiON), aluminum oxide (Al₂O₃), zirconium oxide (ZrOₓ), or the like.

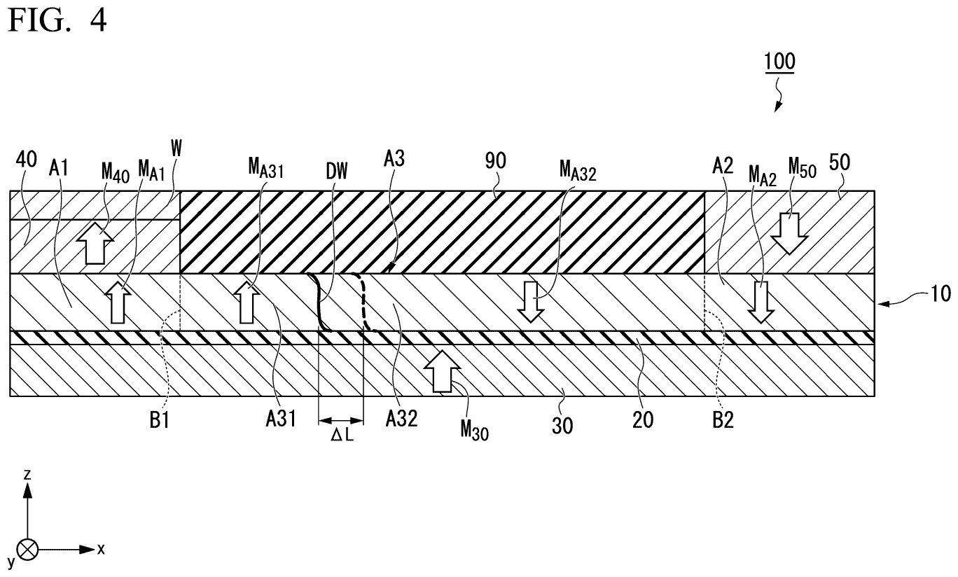

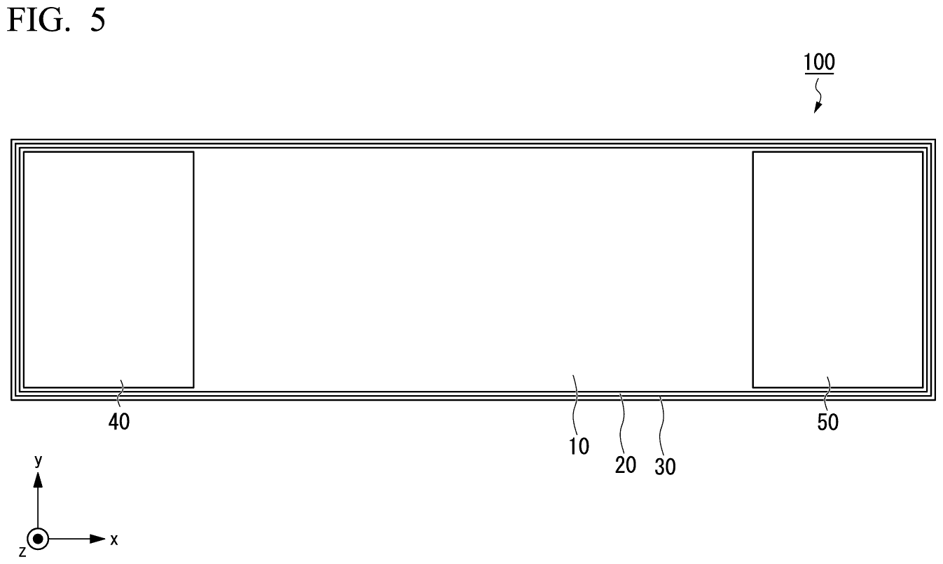

FIG. 4 is a cross-sectional view of the magnetic domain wall motion element 100 cut along an xz plane passing through the center of the magnetic domain wall motion layer 10 in the y direction. The arrows indicated in the diagram are examples of an magnetization orientation direction of a ferromagnetic material. FIG. 5 is a plan view of the magnetic domain wall motion element 100 viewed in the z direction.

For example, the magnetic domain wall motion element 100 has the magnetic domain wall motion layer 10, a nonmagnetic layer 20, a magnetic layer 30, a first magnetization fixed layer 40, and a second magnetization fixed layer 50.

The magnetic domain wall motion layer 10 extends in the x direction. The magnetic domain wall motion layer 10 internally has a plurality of magnetic domains and has magnetic domain walls DW at boundaries between the plurality of magnetic domains. For example, the magnetic domain wall motion layer 10 is a layer capable of magnetically recording information by changing its magnetic state. The magnetic domain wall motion layer 10 is also referred to as an analog layer or a magnetic recording layer.

The magnetic domain wall motion layer 10 has a first area A1, a second area A2, and a third area A3. The first area A1 is an area overlapping the first magnetization fixed layer 40 when viewed in the z direction. The second area A2 is an area overlapping the second magnetization fixed layer 50 when viewed in the z direction. The third area A3 is an area other than the first area A1 and the second area A2 in the magnetic domain wall motion layer 10. For example, the third area A3 is an area sandwiched between the first area A1 and the second area A2 in the x direction.

A magnetization M_{A1} of the first area A1 is fixed by a magnetization M₄₀ of the first magnetization fixed layer 40. A magnetization M_{A2} of the second area A2 is fixed by a magnetization M₅₀ of the second magnetization fixed layer 50. The expression “magnetization being fixed” means that the magnetization does not reverse during normal operation of the magnetic domain wall motion element 100 (when no external force exceeding an assumed level is applied). For example, the magnetization orientation directions of the first area A1 and the second area A2 are opposite to each other.

The third area A3 is an area in which the orientation of the magnetization varies and the magnetic domain wall DW can move. The third area A3 is referred to as a magnetic domain wall movable area. The third area A3 has a first magnetic domain A31 and a second magnetic domain A32. The magnetization orientation directions of the first magnetic domain A31 and the second magnetic domain A32 are opposite to each other. The boundary between the first magnetic domain A31 and the second magnetic domain A32 is the magnetic domain wall DW. For example, a magnetization M_{A31} of the first magnetic domain A31 is oriented in the same direction as the magnetization M_{A1} of the first area A1. For example, a magnetization M_{A32} of the second magnetic domain A32 is oriented in the same direction as the magnetization M_{A2} of the adjacent second area A2. In principle, the magnetic domain wall DW moves within the third area A3 and does not enter the first area A1 and the second area A2.

When the volume ratio between the first magnetic domain A31 and the second magnetic domain A32 within the third area A3 changes, the magnetic domain wall DW moves. The magnetic domain wall DW moves when a write current flows in the x direction of the third area A3, when an external magnetic field is applied to the third area A3, or the like. For example, when a write current in the positive x direction (for example, a current pulse) is applied to the third area A3, electrons flow in the negative x direction opposite to that of the current, and therefore the magnetic domain wall DW moves in the negative x direction. When a current flows from the first magnetic domain A31 toward the second magnetic domain A32, electrons spin-polarized in the second magnetic domain A32 cause magnetization reversal of the magnetization M_{A31} of the first magnetic domain A31. As the magnetization M_{A31} of the first magnetic domain A31 is reversed, the magnetic domain wall DW moves in the negative x direction.

The magnetic domain wall motion layer 10 is composed of a magnetic material. The magnetic domain wall motion layer 10 may be made of a ferromagnetic material, a ferrimagnetic material, or a combination of one of these and an antiferromagnetic material whose magnetic state can be changed using a current. The magnetic domain wall motion layer 10 preferably has at least one element selected from the group consisting of Co, Ni, Fe, Pt, Pd, Gd, Tb, Mn, Ge, and Ga. Examples of materials used for the magnetic domain wall motion layer 10 include a laminated film of Co and Ni, a laminated film of Co and Pt, a laminated film of Co and Pd, a MnGa-based material, a GdCo-based material, and a TbCo-based material. A ferrimagnetic material such as a MnGa-based material, a GdCo-based material, or a TbCo-based material has small saturation magnetization so that a small amount of threshold current is required to move the magnetic domain wall DW. In addition, a laminated film of Co and Ni, a laminated film of Co and Pt, and a laminated film of Co and Pd have a significant coercive force so that the magnetic domain wall DW has a low motion speed. Examples of antiferromagnetic materials include Mn₃X (X is Sn, Ge, Ga, Pt, Ir, or the like), CuMnAs, and Mn₂Au. A material similar to that of the magnetic layer 30 (which will be described below) can also be applied to the magnetic domain wall motion layer 10.

The nonmagnetic layer 20 is positioned between the magnetic domain wall motion layer 10 and the magnetic layer 30. The nonmagnetic layer 20 is laminated on one surface of the magnetic layer 30.

For example, the nonmagnetic layer 20 is made of a nonmagnetic insulating material, a nonmagnetic semiconductor, or a nonmagnetic metal. For example, a nonmagnetic insulating material is Al₂O₃, SiO₂, MgO, MgAl₂O₄, or a material in which a portion of Al, Si, or Mg of these is replaced with Zn, Be, or the like. These materials have a large bandgap and excellent insulation properties. When the nonmagnetic layer 20 is made of a nonmagnetic insulating material, the nonmagnetic layer 20 is a tunnel barrier layer. Examples of nonmagnetic metals include Cu, Au, and Ag. Examples of nonmagnetic semiconductors include Si, Ge, CuInSe₂, CuGaSe₂, and Cu(In,Ga)Se₂.

For example, the thickness of the nonmagnetic layer 20 is 20 Å or larger and may be 25 Å or larger. If the thickness of the nonmagnetic layer 20 is large, the resistance area product (RA) of the magnetic domain wall motion element 100 increases. The resistance area product (RA) of the magnetic domain wall motion element 100 is preferably 1×10⁴ Ωμm² or larger and is more preferably 5×10⁴ Ωμm² or larger. The resistance area product (RA) of the magnetic domain wall motion element 100 is expressed by the product of the element resistance of one magnetic domain wall motion element 100 and the element cross-sectional area of the magnetic domain wall motion element 100 (area of a cut surface of the nonmagnetic layer 20 cut along an xy plane).

The magnetic layer 30 and the magnetic domain wall motion layer 10 sandwich the nonmagnetic layer 20 therebetween. The magnetic layer 30 is located at a position where at least a portion thereof overlaps the magnetic domain wall motion layer 10 in the z direction. The magnetization of the magnetic layer 30 is less likely to be reversed than the magnetization of the third area A3 of the magnetic domain wall motion layer 10. The magnetization of the magnetic layer 30 is fixed such that the direction thereof does not change when an external force has been applied to the extent that the magnetization of the third area A3 is reversed. The magnetic layer 30 may be referred to as a fixed layer or a reference layer.

For example, the magnetic layer 30 contains a ferromagnetic material. The magnetic layer 30 may be made of an antiferromagnetic material such as Mn₃Sn. For example, the magnetic layer 30 contains a material with which a coherent tunneling effect is likely to be achieved between the magnetic layer 30 and the magnetic domain wall motion layer 10. For example, the magnetic layer 30 contains a metal selected from the group consisting of Cr, Mn, Co, Fe and Ni, an alloy containing one or more kinds of these metals, an alloy containing these metals and at least one or more kinds of elements of B, C, and N, or the like. For example, the magnetic layer 30 is made of Co—Fe, Co—Fe—B, or Ni—Fe.

For example, the magnetic layer 30 may be made of a Heusler alloy. A Heusler alloy is a half-metal having a high spin polarizability. A Heusler alloy is an intermetallic compound having a chemical composition of XYZ or X₂YZ. X represents a transition metal element or a noble metal element of the Co group, the Fe group, the Ni group, or the Cu group on the periodic table. Y represents a transition metal of the Mn group, the V group, the Cr group, or the Ti group, or a kind of an element represented by X. Z represents a typical element of Group III to Group V. Examples of a Heusler alloy include Co₂FeSi, Co₂FeGe, Co₂FeGa, Co₂MnSi, Co₂Mn₁₋ₐFeₐAl_{b}Si_{1-b}, and Co₂FeGe_{1-c}Ga_{c}.

The first magnetization fixed layer 40 and the second magnetization fixed layer 50 are connected to the magnetic domain wall motion layer 10. The first magnetization fixed layer 40 and the second magnetization fixed layer 50 are connected to the magnetic domain wall motion layer 10 at different positions. The first magnetization fixed layer 40 and the second magnetization fixed layer 50 are spaced apart in the x direction. The first magnetization fixed layer 40 fixes the magnetization of the first area A1. The second magnetization fixed layer 50 fixes the magnetization of the second area A2.

For example, the first magnetization fixed layer 40 and the second magnetization fixed layer 50 are made of a ferromagnetic material. For example, the same material as those of the magnetic domain wall motion layer 10 and the magnetic layer 30 can be applied to the first magnetization fixed layer 40 and the second magnetization fixed layer 50.

In addition, the first magnetization fixed layer 40 and the second magnetization fixed layer 50 are not limited to being made of a ferromagnetic material. When the first magnetization fixed layer 40 and the second magnetization fixed layer 50 are not made of a ferromagnetic material, the current density of a current flowing through the magnetic domain wall motion layer 10 in an area overlapping the first magnetization fixed layer 40 or the second magnetization fixed layer 50 changes abruptly, thereby restricting the movement of the magnetic domain wall DW and fixing the magnetizations of the first area A1 and the second area A2.

The magnetic domain wall motion element 100 may have a layer other than the magnetic domain wall motion layer 10, the nonmagnetic layer 20, and the magnetic layer 30. For example, a magnetic layer may be provided on a surface of the magnetic layer 30 on a side opposite to the nonmagnetic layer 20 with a spacer layer therebetween. The magnetic layer 30, the spacer layer, and the magnetic layer form a synthetic antiferromagnetic structure (SAF structure). A synthetic antiferromagnetic structure is constituted by two magnetic layers sandwiching a nonmagnetic layer therebetween. When the magnetic layer 30 and the magnetic layer are antiferromagnetically coupled, the coercive force of the magnetic layer 30 becomes greater than in the case of having no magnetic layer. For example, the magnetic layer may include a ferromagnetic material and may also include an antiferromagnetic material such as IrMn or PtMn. For example, the spacer layer includes at least one selected from the group consisting of Ru, Ir, and Rh.

For example, the magnetization direction of each layer in the magnetic domain wall motion element 100 can be confirmed by measuring a magnetization curve. For example, the magnetization curve can be measured using a magneto optical Kerr effect (MOKE). Measurement using the MOKE is a measurement method performed using a magneto-optical effect (magnetic Kerr effect) in which linearly polarized light is incident on a measurement target, causing rotation or the like in its polarization direction.

In the magnetic domain wall motion element 100 according to the present embodiment, the conductance in the lamination direction varies depending on the position of the magnetic domain wall DW. For example, in the case of the configuration in FIG. 4, when the magnetic domain wall DW is located at a boundary B1 between the first area A1 and the third area A3, the conductance shows the smallest value (the resistance shows the largest value), and when the magnetic domain wall DW is located at a boundary B2 between the second area A2 and the third area A3, the conductance shows the largest value (the resistance shows the smallest value).

The pulse application device 3 is configured to be capable of controlling the conductance of the magnetic domain wall motion element 100 by applying a write pulse to the magnetic domain wall motion element 100.

The pulse application device 3 is configured to be capable of applying a magnetic domain wall driving pulse and a mode change pulse as write pulses. The magnetic domain wall driving pulse and the mode change pulse will be described together with a write operation with respect to the magnetic domain wall motion element 100.

When data is written to the magnetic domain wall motion element 100, a write pulse is applied to the magnetic domain wall motion element 100. When a write pulse is applied to the magnetic domain wall motion element 100, the magnetic domain wall DW moves in the x direction within the range of the third area A3. For example, in the configuration shown in FIG. 4, as the magnetic domain wall DW moves to the right side from the boundary B1, the conductance of the magnetic domain wall motion element 100 increases, and as the magnetic domain wall DW moves to the left side from the boundary B2, the conductance of the magnetic domain wall motion element 100 decreases.

The magnetic domain wall DW can move to any position in the x direction of the third area A3 of the magnetic domain wall motion layer 10. However, in order to ensure stable movement of the magnetic domain wall DW, it is necessary for a movement amount ΔL1 of the magnetic domain wall DW moving with a single application of a write pulse to be a certain amount or larger.

This is because the movement of the magnetic domain wall DW is determined probabilistically. When a write pulse (pulse length, applied voltage) having sufficient magnitude is applied to the magnetic domain wall motion layer 10, the magnetic domain wall DW moves nearly 100%. Here, the magnitude of a write pulse refers to the amount of energy of a write pulse, which is determined by the pulse length, the applied voltage, and the like.

In contrast, when the magnitude of a write pulse is insufficient, whether or not the magnetic domain wall DW moves is determined probabilistically. That is, when the magnitude of a write pulse is insufficient, even if the same write pulse is applied, the magnetic domain wall DW may move in some cases and may not move in other cases.

In order to stably control the position of the magnetic domain wall DW, it is necessary to reliably move the magnetic domain wall DW with a write pulse, and therefore it is necessary to apply a write pulse having sufficient magnitude. As a result, the movement amount ΔL1 of the magnetic domain wall DW caused by a single application of a write pulse inevitably becomes a certain amount or larger.

Here, a write pulse having sufficient magnitude to move the magnetic domain wall DW can be obtained from the actual magnetic domain wall motion element 100 as follows. First, the magnetic domain wall DW is moved to a position different from the boundary B1 or the boundary B2. In this state, a write pulse is applied, and the conductance change amount of the magnetic domain wall motion element 100 before and after the application of the write pulse is obtained. When this processing is performed at least 100 times, and when the conductance changes in all 100 cases, it can be said that the write pulse has sufficient magnitude. A write pulse sufficient to move this magnetic domain wall DW is referred to as a magnetic domain wall driving pulse.

The average value of the conductance change amounts obtained when a write pulse is applied 100 times is set as a conductance change amount ΔG1 caused by the magnetic domain wall motion pulse. The conductance change amount ΔG1 is a conductance change resulting from the magnetic domain wall DW moving by the movement amount ΔL1.

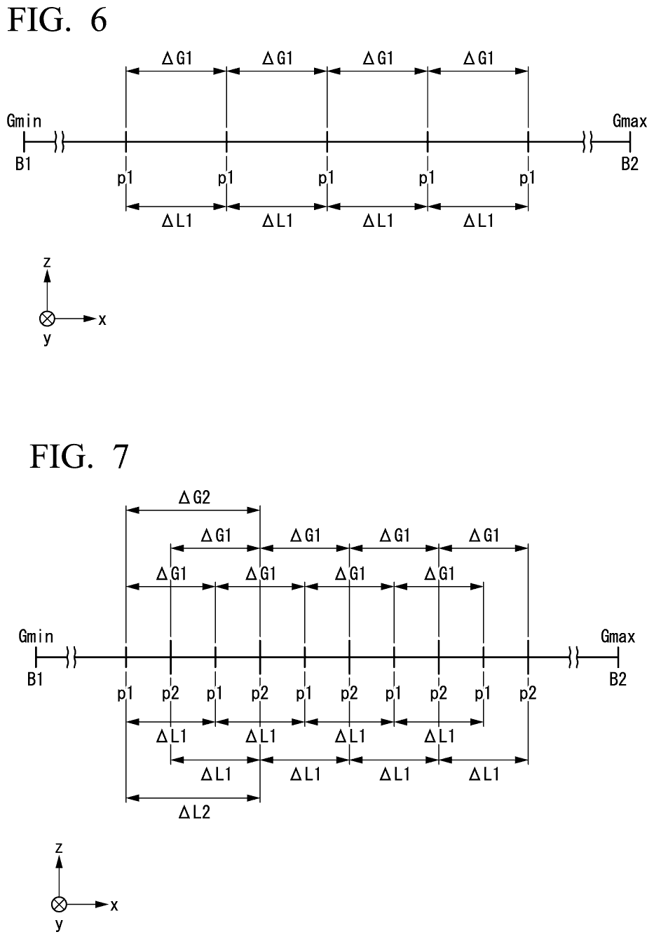

FIG. 6 is a schematic diagram showing relationships between positions p1 of the magnetic domain wall DW, the movement amount ΔL1 of the magnetic domain wall DW, and the conductance change amount ΔG1 when the magnetic domain wall DW is moved using only the magnetic domain wall motion pulse. When the magnetic domain wall motion pulse is applied to the magnetic domain wall motion element 100, the magnetic domain wall DW moves between the boundary B1 and the boundary B2 at intervals of the movement amount ΔL1. The magnetic domain wall DW stops at the positions p1 at intervals of the movement amount ΔL1. By applying a write pulse (magnetic domain wall motion pulse) a plurality of times, the magnetic domain wall DW can move to any of the positions p1.

The mode change pulse is a pulse having a longer pulse length than the magnetic domain wall driving pulse. For example, the pulse length of the mode change pulse may be 1.2 to 1.8 times the pulse length of the magnetic domain wall driving pulse, may be 1.4 to 1.6 times, or may be 1.5 times. For example, the applied voltage of the mode change pulse may be 0.9 to 1.1 times the applied voltage of the magnetic domain wall driving pulse, or may be 1.0 times. Since the mode change pulse is larger than the magnetic domain wall driving pulse, the magnetic domain wall DW can be moved stably.

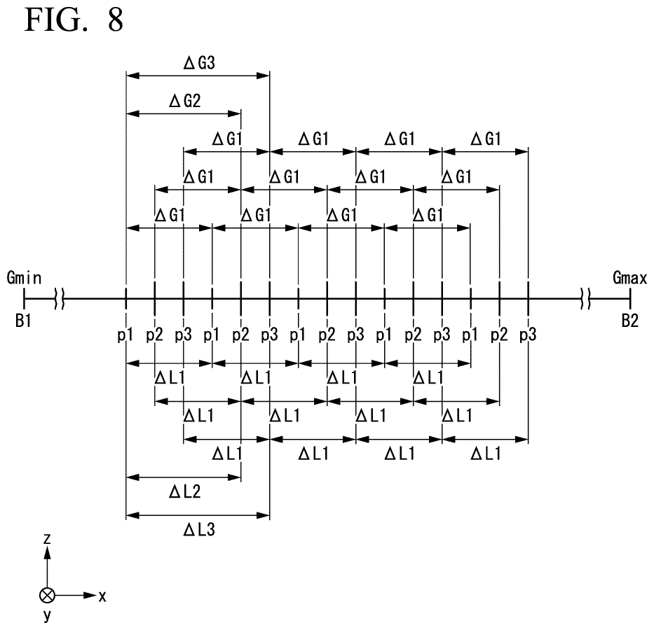

FIG. 7 is a schematic diagram showing relationships between the positions p1 and p2 of the magnetic domain wall DW, the movement amounts ΔL1 and ΔL2 of the magnetic domain wall DW, and the conductance change amounts ΔG1 and ΔG2 when the magnetic domain wall DW is moved using a magnetic domain wall motion pulse and a mode change pulse.

Similar to FIG. 6, when the magnetic domain wall motion pulse is applied to the magnetic domain wall motion element 100, the magnetic domain wall DW moves between the boundary B1 and the boundary B2 at intervals of the movement amount ΔL1. The magnetic domain wall DW can stop at the positions p1 at intervals of the movement amount ΔL1. By applying a write pulse (magnetic domain wall motion pulse) a plurality of times, the magnetic domain wall DW can move to any of the positions p1.

When the mode change pulse is applied to the magnetic domain wall motion element 100, the magnetic domain wall DW moves by the movement amount ΔL2. Since the mode change pulse is larger than the magnetic domain wall driving pulse, the movement amount ΔL2 is larger than the movement amount ΔL1. When the mode change pulse is applied, the magnetic domain wall DW can move from the position p1 to the position p2. After the magnetic domain wall DW has moved to the position p2, the magnetic domain wall DW can stop at each of the positions p2 at intervals of the movement amount ΔL1 by applying the magnetic domain wall driving pulse one or more times.

When the magnetic domain wall driving pulse and the mode change pulse are used, the magnetic domain wall DW can stop at each of the boundary B1, a plurality of positions p1, a plurality of positions p2, and the boundary B2. The magnetic domain wall motion element 100 exhibits a different conductance depending on the stop position of the magnetic domain wall DW. That is, the magnetic domain wall motion element 100 can exhibit conductance levels corresponding to the stop positions of the magnetic domain wall DW. The number of conductance levels of the magnetic domain wall motion element 100 corresponds to the total number of the boundary B1, the boundary B2, the plurality of positions p1, and the plurality of positions p2.

The pulse application device 3 is configured to be capable of determining whether or not application of the mode change pulse is necessary based on the conductance before updating and the conductance after updating in the process of updating the conductance of the magnetic domain wall motion element 100.

For example, the process of updating the conductance of the magnetic domain wall motion element 100 corresponds to a data rewriting step when the magnetic array MA is used as a memory and corresponds to a weight updating step when the magnetic array MA is used as a neuromorphic device.

For example, when the conductance change amount before and after updating is an integral multiple of the conductance change amount ΔG1, the pulse application device 3 may determine that application of the mode change pulse is unnecessary. This is because the conductance change amount before and after updating corresponds to a transition between the positions p1 or a transition between the positions p2 when it is an integral multiple of the conductance change amount ΔG1.

On the other hand, when the conductance change amount before and after updating is other than an integral multiple of the conductance change amount ΔG1, the pulse application device 3 may determine that it is necessary to apply the mode change pulse. This is because a transition from the position p1 to the position p2 or a transition from the position p2 to the position p1 is required when the conductance change amount before and after updating is other than an integral multiple of the conductance change amount ΔG1.

Here, determining whether or not application of the mode change pulse by the pulse application device 3 is necessary is not limited to whether or not the conductance change amount before and after updating exactly matches an integral multiple of the conductance change amount ΔG1. For example, the pulse application device 3 may determine that application of the mode change pulse is unnecessary when the conductance change amount before and after updating falls within a certain margin relative to an integral multiple of the conductance change amount ΔG1. For example, the pulse application device may determine that application of the mode change pulse is unnecessary when the conductance change amount before and after updating is 0.9 to 1.1 times an integral multiple of the conductance change amount ΔG1.

In one process of updating the conductance of the magnetic domain wall motion element 100, the number of times of application of the mode change pulse is set to be equal to or smaller than the number of times of application of the magnetic domain wall driving pulse. For example, in one process of updating the conductance of the magnetic domain wall motion element 100, the number of times of application of the mode change pulse may be one. Since the mode change pulse is larger than the magnetic domain wall driving pulse, this causes heat generation in the magnetic domain wall motion element 100. When the temperature of the magnetic domain wall motion element 100 rises, the stability of the magnetic domain wall DW decreases.

In one process of updating the conductance, the timing of application of the mode change pulse may be before application of all of the magnetic domain wall driving pulses or after application of all of the magnetic domain wall driving pulses. By collectively applying the magnetic domain wall driving pulse, the number of times of switching between the magnetic domain wall driving pulse and the mode change pulse in the pulse application device 3 can be reduced, control of the pulse application device 3 can be simplified, and arithmetic operation processing of the pulse application device 3 can be accelerated.

In addition, in one process of updating the conductance, the timing of application of the mode change pulse may be after application of all of the magnetic domain wall driving pulses. As described above, the mode change pulse further promotes heat generation in the magnetic domain wall motion element 100 than the magnetic domain wall driving pulse. By applying the mode change pulse at the end of one process of updating the conductance, it is possible to avoid further application of write pulses to the magnetic domain wall motion element 100 in a heated state.

In addition, in one process of updating the conductance, the polarities of the mode change pulse and the magnetic domain wall driving pulse corresponding to positive and negative polarities relative to a reference voltage of the applied voltage may be opposite. Here, the reference voltage is a voltage serving as a reference for determining whether the magnetic domain wall DW moves rightward or leftward. For example, when the polarity of a pulse that moves the magnetic domain wall DW rightward is set to be positive, the polarity of a pulse that moves the magnetic domain wall DW leftward is set to be negative. If the polarities of the mode change pulse and the magnetic domain wall driving pulse are opposite, a transition from the position p1 to the nearest position p2 or a transition from the position p2 to the nearest position p1 becomes easier.

Thus far, a case where there is one kind of mode change pulse has been described as an example, but there may be a plurality of kinds of mode change pulses. The pulse lengths of the respective mode change pulses differ.

FIG. 8 is a schematic diagram showing relationships between the positions p1, p2, and p3 of the magnetic domain wall DW, the movement amounts ΔL1, ΔL2, and ΔL3 of the magnetic domain wall DW, and the conductance change amounts ΔG1, ΔG2, and ΔG3 when the magnetic domain wall DW is moved using a magnetic domain wall motion pulse and a plurality of mode change pulses.

For example, when a first mode change pulse is applied to the magnetic domain wall motion element 100, the magnetic domain wall DW moves by the movement amount ΔL2. When the first mode change pulse is applied, the magnetic domain wall DW can move from the position p1 to the position p2. After the magnetic domain wall DW has moved to the position p2, the magnetic domain wall DW can stop at each of the positions p2 at intervals of the movement amount ΔL1 by applying the magnetic domain wall driving pulse one or more times.

Similarly, for example, when a second mode change pulse is applied to the magnetic domain wall motion element 100, the magnetic domain wall DW moves by the movement amount ΔL3. When the second mode change pulse is applied, the magnetic domain wall DW can move from the position p1 to the position p3. After the magnetic domain wall DW has moved to the position p3, the magnetic domain wall DW can stop at each of the positions p3 at intervals of the movement amount ΔL1 by applying the magnetic domain wall driving pulse one or more times.

When the magnetic domain wall driving pulse and a plurality of mode change pulses are used, the magnetic domain wall DW can stop at each of the boundary B1, a plurality of positions p1, a plurality of positions p2, a plurality of positions p3, and the boundary B2. The magnetic domain wall motion element 100 can exhibit conductance levels corresponding to the stop positions of the magnetic domain wall DW, thereby increasing the number of conductance levels of the magnetic domain wall motion element 100.

When a plurality of mode change pulses are used, the pulse application device 3 is configured to be capable of determining whether or not application of the mode change pulse is necessary based on the conductance before updating and the conductance after updating and which mode change pulse is to be applied and how many times the pulse is to be applied in the process of updating the conductance of the magnetic domain wall motion element 100.

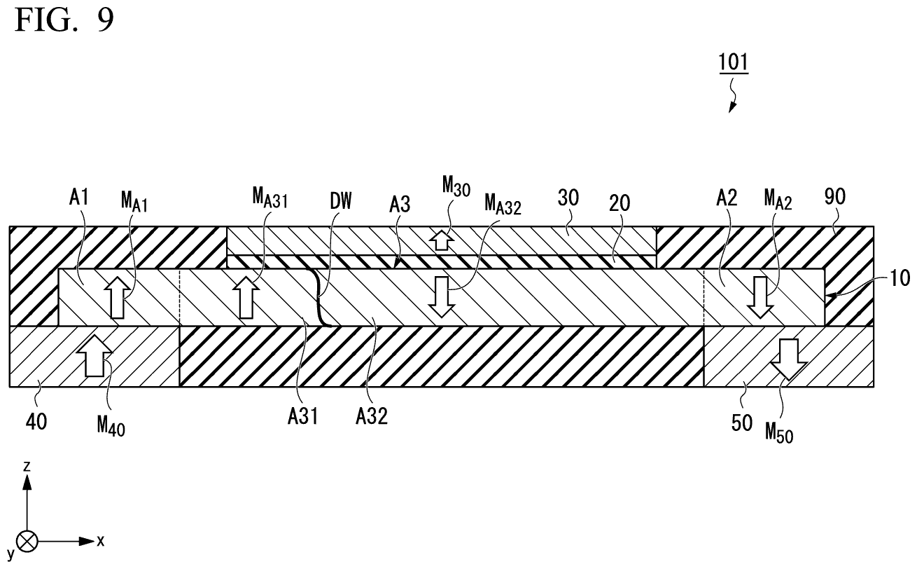

Thus far, the magnetic domain wall motion element 100 shown in FIG. 4 has been described as an example of a specific configuration of a magnetic domain wall motion element, but the structure of the magnetic domain wall motion element is not limited to this case. FIG. 9 is a cross-sectional view of a magnetic domain wall motion element 101 according to a modification example cut along an xz plane passing through the center of the magnetic domain wall motion layer 10 in the y direction. The magnetic domain wall motion element 101 shown in FIG. 9 differs from the magnetic domain wall motion element 100 in that the magnetic layer 30 is located at a position farther from the substrate Sub than the magnetic domain wall motion layer 10. In the magnetic domain wall motion element 101, the magnetic layer 30 serving as a fixed layer is located at a position away from the substrate Sub, and this is referred to as a top-pinned structure. In the magnetic domain wall motion element 100, the magnetic layer 30 serving as a fixed layer is located closer to the substrate Sub than the magnetic domain wall motion layer 10, and this is referred to as a bottom-pinned structure. The magnetic domain wall motion element 100 can be replaced with the magnetic domain wall motion element 101.

The magnetic domain wall motion element 100 is formed through a lamination step for each of the layers, and a processing step of processing a part of each of the layers into a predetermined shape. Each of the layers can be laminated using a sputtering method, a chemical vapor deposition (CVD) method, an electron beam evaporation method (EB evaporation method), an atom laser deposition method, or the like. The layers can be processed using photolithography, etching (for example, Ar etching), and the like.

Next, a method of controlling the magnetic array MA will be described. The method of controlling the magnetic array MA has a signal writing step and a signal reading step.

First, the signal writing step will be described. First, in the writing step, at least one of the magnetic domain wall driving pulse and the mode change pulse is applied to the magnetic domain wall motion element 100 as a write pulse.

The magnitudes of the magnetic domain wall driving pulse and the mode change pulse are set in advance. As described above, the magnetic domain wall driving pulse is set to a magnitude capable of stably moving the magnetic domain wall DW. The magnetic domain wall driving pulse may be the smallest magnitude capable of stably moving the magnetic domain wall DW. The mode change pulse is set to have a longer pulse length than the magnetic domain wall driving pulse. The mode change pulse is set such that the conductance change amount ΔG2 of the magnetic domain wall motion element 100 when the mode change pulse is applied does not become an integral multiple of the conductance change amount ΔG1 of the magnetic domain wall motion element 100 when the magnetic domain wall driving pulse is applied. Once the write pulse is set as a preliminary preparation, it is not necessary to perform this setting for each subsequent write operation. For example, this setting is performed by executing a setting program stored in the control unit 6.

Next, a step of writing an actual signal to the magnetic array MA is performed. The writing step is performed by applying a write pulse to the magnetic domain wall motion element 100. For example, this writing step is performed by a processor executing a write program stored in the control unit 6.

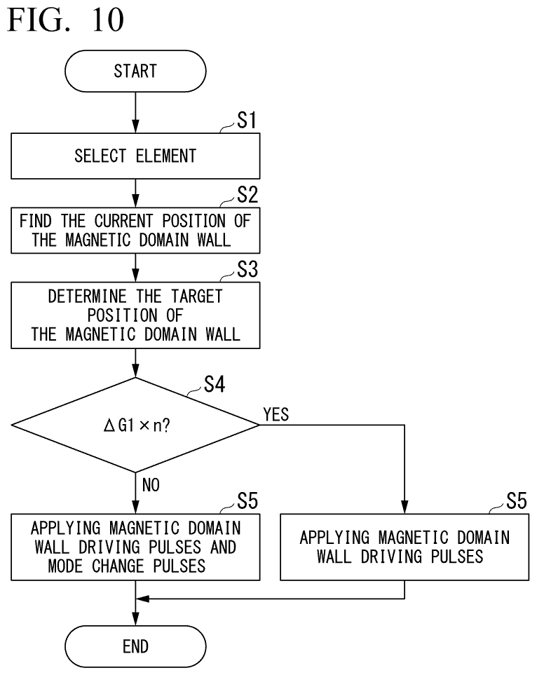

FIG. 10 is a flowchart of the writing step of the magnetic array MA. The writing step has an element selection step S1, a current position identification step S2, a destination identification step S3, a pulse determination step S4, and a pulse application step S5. The current position identification step S2, the destination identification step S3, and the pulse determination step S4 correspond to determination steps.

In the element selection step S1, the magnetic domain wall motion element 100 to which a pulse is to be applied is selected. When the magnetic array MA is used as a magnetic memory, the magnetic domain wall motion element 100 to which a pulse is to be applied serves as an element that stores data. When the magnetic array MA is used as a neural network, the magnetic domain wall motion element 100 to which a pulse is to be applied is an element that performs learning.

A magnetic domain wall motion element 100 of a plurality of magnetic domain wall motion elements 100 to which a pulse is to be applied is controlled by the control unit 6 in accordance with the control program. The control unit 6 turns on the first switching element SW1 and the second switching element SW2 connected to the magnetic domain wall motion element 100 to which a pulse is to be applied, and turns off the first switching elements SW1 and the second switching elements SW2 connected to other magnetic domain wall motion elements 100.

In the current position identification step S2, the conductance at the present time of the magnetic domain wall motion element 100 (which will hereinafter be referred to as a first conductance) is identified. The target for identifying the first conductance is a magnetic domain wall motion element that is a write target. The first conductance corresponds to the position of the magnetic domain wall DW of the magnetic domain wall motion element 100. The first conductance may be identified based on write data in the past, or may be obtained by actually reading the conductance of the element. By performing the current position identification step S2, it is possible to identify at which of the boundary B1, the boundary B2, a plurality of positions p1, and a plurality of positions p2 the magnetic domain wall DW is located.

In the destination identification step S3, a target conductance after a write operation is performed on the magnetic domain wall motion element 100 (which will hereinafter be referred to as a second conductance) is identified. The target for identifying the second conductance is a magnetic domain wall motion element that is a write target. The second conductance corresponds to the position of the magnetic domain wall DW of the magnetic domain wall motion element 100. By performing the destination identification step S3, it is possible to identify to which of the boundary B1, the boundary B2, a plurality of positions p1, and a plurality of positions p2 the magnetic domain wall DW moves after application of the write pulse.

In the pulse determination step S4, it is determined whether or not application of the mode change pulse is necessary based on the conductance change amount before and after updating of the magnetic domain wall motion element 100. For example, when the conductance change amount before and after updating is an integral multiple of the conductance change amount ΔG1, it may be determined that application of the mode change pulse is unnecessary, and when the conductance change amount before and after updating is not an integral multiple of the conductance change amount ΔG1, it may be determined that application of the mode change pulse is necessary. In the pulse determination step S4, the numbers of times of application of the magnetic domain wall driving pulse and the mode change pulse are also determined.

In the pulse application step S5, a write pulse is applied to the magnetic domain wall motion element 100 that is a write target in accordance with the determination in the pulse determination step S4. The write pulse may have a rectangular waveform, a spike waveform, or other waveforms.

As described above, the magnetic array MA completes the writing step when a computer executes the write program.

Next, a step of reading a signal from the magnetic array MA will be described. For example, the reading step is performed by a processor executing a read program stored in the control unit 6. The read program is one of the control programs.

The read program has a procedure of selecting a magnetic domain wall motion element 100 to which a pulse is to be applied, and a procedure of applying a pulse.

First, the pulse application device 3 selects a magnetic domain wall motion element 100 to which a read pulse is to be applied in accordance with the read program. When the magnetic array MA is used as a magnetic memory, the magnetic domain wall motion element 100 to which a read pulse is to be applied is an element that reads data. When the magnetic array MA is used as a neural network, application of a read pulse to a predetermined magnetic domain wall motion element 100 corresponds to multiplication operation of an input and a weight. That is, when the magnetic array MA is used as a neural network, the reading step is identification operation of the neural network.

A magnetic domain wall motion element 100 of a plurality of magnetic domain wall motion elements 100 to which a pulse is to be applied is controlled by the control unit 6. The control unit 6 turns on the third switching element SW3 and the second switching element SW2 connected to the magnetic domain wall motion element 100 to which a pulse is to be applied, and turns off the third switching elements SW3 and the second switching elements SW2 connected to other magnetic domain wall motion elements 100.

Next, the pulse application device 3 applies a read pulse to a predetermined magnetic domain wall motion element 100 in accordance with the read program. For example, a read pulse is applied between the magnetic layer 30 and the second magnetization fixed layer 50. The voltage of a read pulse is a voltage capable of obtaining a current density lower than a critical current density required to move the magnetic domain wall DW of the magnetic domain wall motion layer 10. That is, a read pulse does not move the magnetic domain wall DW.

The resistance detection device 4 detects the resistance value of the magnetic domain wall motion element 100 to which a read pulse has been applied. For example, the output unit 5 outputs the arithmetic operation results to the outside.

In the magnetic domain wall motion element 100 according to the present embodiment, the number of positions p1 and p2 of the magnetic domain wall DW is large by switching between the magnetic domain wall driving pulse and the mode change pulse. The number of conductance levels of the magnetic domain wall motion element 100 is the total number of the boundary B1, the boundary B2, a plurality of positions p1, and a plurality of positions p2. The magnetic domain wall motion element 100 according to the present embodiment can realize multiple conductance levels even with a small element by increasing the positions where the magnetic domain wall DW can stop.

Here, it is not possible to realize a magnetic domain wall motion element 100 having the same number of conductance levels as the magnetic domain wall motion element 100 according to the present embodiment by reducing the magnitude of a write pulse. This is because the magnetic domain wall DW does not move stably when the magnitude of a write pulse is reduced.

In addition, according to the method of controlling the magnetic domain wall motion element 100 and the recording media including a control program according to the present embodiment, a write operation of the magnetic domain wall motion element 100 having multiple conductance levels can be performed stably.

The magnetic array MA according to the present embodiment can be applied to a neuromorphic device.

For example, a neuromorphic device has the magnetic array MA and an output conversion unit. The output conversion unit has an activation function. The output conversion unit has the resistance detection device 4 and the output unit 5. The output conversion unit converts product-sum operation results output from the second wiring CL in accordance with the activation function.

The neuromorphic device is a device that performs arithmetic operation of a neural network. The neuromorphic device artificially mimics the relationship between neurons and synapses in the human brain.

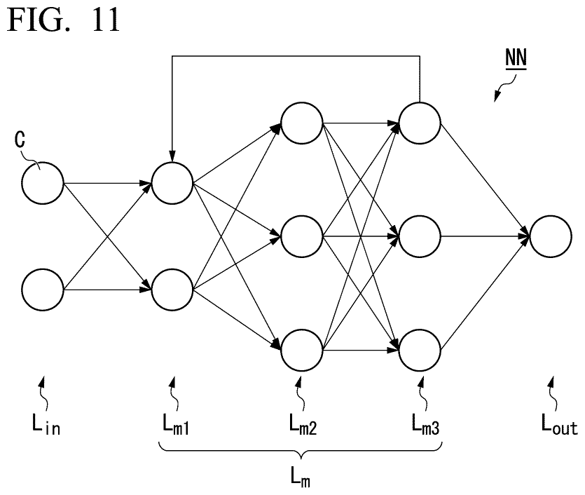

FIG. 11 is a schematic view of a neural network NN. The neural network NN has an input layer Lᵢₙ, an intermediate layer Lₘ, and an output layer Lₒᵤₜ. FIG. 11 presents an example having three intermediate layers Lₘ, but the number of intermediate layers Lₘ does not matter. Each of the input layer Lᵢₙ, the intermediate layer Lₘ, and the output layer Lₒᵤₜ has a plurality of chips C, and each of the chips C corresponds to the neuron in the brain. The input layer Lᵢₙ, the intermediate layer Lₘ, and the output layer Lₒᵤₜ are connected to each other via a transmission means. The transmission means corresponds to the synapses in the brain. In the neural network NN, the transmission means (synapses) performs learning to increase the rate of correct answer to a problem. Learning is a process of finding knowledge which is prone to be used in the future from information. The neural network NN performs learning through operation while changing the weight applied to the transmission means. The transmission means performs multiplication operation of multiplying an input signal by a weight, and addition operation of adding results of the multiplication operation. That is, the transmission means performs product-sum operation.

The magnetic array MA can perform product-sum operation. In the magnetic domain wall motion element 100, the resistance value changes to a multi-value form or an analog form due to change in the position of the magnetic domain wall DW. Designing the resistance value of the magnetic domain wall motion element 100 and the conductance which is a reciprocal thereof corresponds to imparting a weight to the transmission means.

For example, in FIG. 2, a current is caused to flow from the third wiring RL toward the second wiring CL. The current (output value) output from the second wiring CL varies depending on the conductance (weight) of the magnetic domain wall motion element 100. That is, applying a current from the third wiring RL toward the second wiring CL corresponds to multiplication operation in the neural network NN. In addition, the second wiring CL is connected to a plurality of magnetic domain wall motion elements 100 which belong to the same column, and a current detected in the end portion of the second wiring CL is a value obtained by performing addition operation of results of multiplication operation in each of the magnetic domain wall motion elements 100. Therefore, the magnetic array MA functions as a product-sum operation unit of the neuromorphic device.

Hereinabove, preferred embodiment of the present disclosure has been described in detail, but the present disclosure is not limited to the embodiment. For example, characteristic configurations of the embodiment may be combined, and a part may be changed within a range not changing the gist of the invention.

### REFERENCE SIGNS LIST

1 Integrated area
2 Peripheral area
3 Pulse application device
4 Resistance detection device
5 Output unit
6 Control unit
7 Power source
10 Magnetic domain wall motion layer
20 Nonmagnetic layer
30 Magnetic layer
40 First magnetization fixed layer
50 Second magnetization fixed layer
90 Insulation layer
100, 101 Magnetic domain wall motion element
A1 First area
A2 Second area
A3 Third area
A31 First magnetic domain
A32 Second magnetic domain
B1, B2 Boundary
DW Magnetic domain wall
MA Magnetic array
P1, p2, p3 Position
S1 Element selection step
S2 Current position identification step
S3 Destination identification step
S4 Pulse determination step
S5 Pulse application step

1. A magnetic array comprising:
a plurality of memristors; and
a pulse application device,
wherein the pulse application device is configured to be capable of applying, as write pulses, a magnetic domain wall driving pulse and a mode change pulse to at least one of the plurality of memristors,
each of the plurality of memristors includes a magnetic domain wall motion layer, a ferromagnetic layer, and a nonmagnetic layer,
the nonmagnetic layer is sandwiched between the magnetic domain wall motion layer and the ferromagnetic layer,
a conductance of a laminate including the magnetic domain wall motion layer, the ferromagnetic layer, and the nonmagnetic layer varies depending on a change in position of a magnetic domain wall in the magnetic domain wall motion layer,
in a process of updating the conductance, the pulse application device is configured to be capable of determining whether or not application of the mode change pulse is necessary based on the conductance of the laminate before updating and the conductance of the laminate after updating,
the mode change pulse has a longer pulse length than the magnetic domain wall driving pulse, and
in one process of updating the conductance, the number of times of application of the mode change pulse is equal to or smaller than the number of times of application of the magnetic domain wall driving pulse.

2. The magnetic array according to claim 1,
wherein the pulse length of the mode change pulse is 1.4 to 1.6 times the pulse length of the magnetic domain wall driving pulse.

3. The magnetic array according to claim 1,
wherein an applied voltage of the mode change pulse is 0.9 to 1.1 times an applied voltage of the magnetic domain wall driving pulse.

4. The magnetic array according to claim 1,
wherein in one process of updating the conductance, the mode change pulse and the magnetic domain wall driving pulse have opposite pulse polarities corresponding to positive and negative polarities relative to a reference voltage of the applied voltage.

5. The magnetic array according to claim 1,
wherein in one process of updating the conductance, the number of times of application of the mode change pulse is one.

6. The magnetic array according to claim 1,
wherein in one process of updating the conductance, a timing of application of the mode change pulse is before application of all of the magnetic domain wall driving pulses or after application of all of the magnetic domain wall driving pulses.

7. The magnetic array according to claim 1,
wherein there are a plurality of kinds of the mode change pulses, and
pulse lengths of the respective mode change pulses differ.

8. A method of controlling a magnetic array, comprising:
a writing step of applying, as a write pulse, at least one of a magnetic domain wall driving pulse and a mode change pulse to a memristor including a magnetic domain wall motion layer, a ferromagnetic layer, and a nonmagnetic layer sandwiched between the magnetic domain wall motion layer and the ferromagnetic layer,
wherein the writing step includes a determination step and an application step,
in the determination step, it is determined, in a process of updating a conductance, whether or not application of the mode change pulse is necessary based on the conductance of the memristor before updating and the conductance of the memristor after updating,
in the application step, at least one of the magnetic domain wall driving pulse and the mode change pulse is applied to the memristor a predetermined number of times,
the mode change pulse has a longer pulse length than the magnetic domain wall driving pulse, and
in one process of updating the conductance, the number of times of application of the mode change pulse is equal to or smaller than the number of times of application of the magnetic domain wall driving pulse.

9. The method of controlling a magnetic array according to claim 8,
wherein the pulse length of the mode change pulse is 1.4 to 1.6 times the pulse length of the magnetic domain wall driving pulse.

10. The method of controlling a magnetic array according to claim 8,
wherein an applied voltage of the mode change pulse is 0.9 to 1.1 times an applied voltage of the magnetic domain wall driving pulse.

11. The method of controlling a magnetic array according to claim 8,
wherein in one process of updating the conductance, the mode change pulse and the magnetic domain wall driving pulse have opposite pulse polarities corresponding to positive and negative polarities relative to a reference voltage of the applied voltage.

12. The method of controlling a magnetic array according to claim 8,
wherein in one process of updating the conductance, the number of times of application of the mode change pulse is one.

13. The method of controlling a magnetic array according to claim 8,
wherein in one process of updating the conductance, a timing of application of the mode change pulse is before application of all of the magnetic domain wall driving pulses or after application of all of the magnetic domain wall driving pulses.

14. The method of controlling a magnetic array according to claim 8,
wherein there are a plurality of kinds of the mode change pulses,
pulse lengths of the respective mode change pulses differ, and
the method further comprises a mode changing step of determining which of the plurality of kinds of the mode change pulses is to be applied and how many times the pulse is to be applied when it is determined, in the determination step, that application of the mode change pulse is necessary.

15. A computer-readable recording medium including a program,
wherein the program includes a write program for applying, as a write pulse, at least one of a magnetic domain wall driving pulse and a mode change pulse to a memristor including a magnetic domain wall motion layer, a ferromagnetic layer, and a nonmagnetic layer sandwiched between the magnetic domain wall motion layer and the ferromagnetic layer,
the write program includes a determination program and an application program,
the determination program determines, in a process of updating a conductance, whether or not application of the mode change pulse is necessary based on the conductance of the memristor before updating and the conductance of the memristor after updating,
the application program issues an instruction to apply at least one of the magnetic domain wall driving pulse and the mode change pulse to the memristor a predetermined number of times,
the mode change pulse has a longer pulse length than the magnetic domain wall driving pulse, and
in one process of updating the conductance, the number of times of application of the mode change pulse is equal to or smaller than the number of times of application of the magnetic domain wall driving pulse.

16. The recording medium according to claim 15,
wherein the pulse length of the mode change pulse is 1.4 to 1.6 times the pulse length of the magnetic domain wall driving pulse.

17. The recording medium according to claim 15,
wherein an applied voltage of the mode change pulse is 0.9 to 1.1 times an applied voltage of the magnetic domain wall driving pulse.

18. The recording medium according to claim 15,
wherein in one process of updating the conductance, the mode change pulse and the magnetic domain wall driving pulse have opposite pulse polarities corresponding to positive and negative polarities relative to a reference voltage of the applied voltage.

19. The recording medium according to claim 15,
wherein in one process of updating the conductance, the number of times of application of the mode change pulse is one.

20. The recording medium according to claim 15,
wherein in one process of updating the conductance, a timing of application of the mode change pulse is before application of all of the magnetic domain wall driving pulses or after application of all of the magnetic domain wall driving pulses.
